(19) United States
(12) Patent Application Publication
(10) Pub. No.: US 2024/0305246 A1
(43) Pub. Date: Sep. 12, 2024

(54) Switching Amplifier Circuits with Supply Tracking

(71) Applicant: Apple Inc., Cupertino, CA (US)

(72) Inventors: Eddie L. Ng, San Jose, CA (US); Adriane S. Niehaus, Wilton, NH (US); Ali Motamed, San Francisco, CA (US)

(21) Appl. No.: 18/182,101

(22) Filed: Mar. 10, 2023

(51) Int. Cl. H03F 1/02; H03F 3/217

(52) U.S. Cl. CPC H03F 1/0211; H03F 3/2171

(57) ABSTRACT

A switching-amplifier circuit for computer systems generates a buffered version of a received input signal. Power supply circuits coupled to the switching-amplifier circuit adjust driver power supply and driver ground supply voltage levels over respective continuous ranges of voltages based on a magnitude of the buffered signal. An output stage included in the switching-amplifier circuit generates an amplified version of the received input signal that includes a series of pulses that transition between the respective voltage ranges of the driver power supply and driver ground supply, where the respective widths or frequencies of the series of pulses encode a magnitude of the amplified version of the received input signal.

### BACKGROUND

### Technical Field

This disclosure relates to signal amplification in computer systems and, more particularly, to switching amplifier circuits.

### Description of the Related Art

In computer systems, some signals lack sufficient amplitude to be used directly. In such cases, an amplifier circuit can be employed to amplify the signal so that it can be further processed. For example, a radio-frequency signal received via an antenna may be amplified before being filtered, converted to the digital domain, and the like. Alternatively, some signals need to be amplified to drive a heavy load such as a speaker, an antenna, etc.

To accomplish such amplification, computer systems can employ a variety of amplifier circuits. Depending on a particular application, a given amplifier circuit may be chosen based on its efficiency, frequency response, circuit area, or any other suitable metric.

### BRIEF DESCRIPTION OF THE DRAWINGS

FIG. 1 is a block diagram of an embodiment of a supply tracking amplifier circuit for a computer system.

FIG. 2 is a block diagram of an embodiment of a switching amplifier circuit that can be included in a supply tracking amplifier circuit.

FIG. 3 is a block diagram of an embodiment of an output stage of a switching amplifier circuit.

FIG. 4 is a block diagram of an embodiment of an audio sub-system for a computer system.

FIG. 5 illustrates example waveforms associated with the switching range of a switching amplifier circuit.

FIG. 6 illustrates example waveforms associated with the continuous adjustment of driver power and ground levels for a switching amplifier circuit.

FIG. 7 illustrates different waveforms associated with the continuous adjustment of driver power and ground levels for a switching amplifier circuit.

FIG. 8 illustrates alternative waveforms associated with the continuous adjustment of driver power and ground levels for a switching amplifier circuit.

FIG. 9 is a flow diagram depicting an embodiment of a method for operating a switching amplifier circuit.

FIG. 10 is a block diagram of one embodiment of a system-on-a-chip that includes a power management circuit.

FIG. 11 is a block diagram of various embodiments of computer systems that may include power management circuits.

FIG. 12 illustrates an example of a non-transitory computer-readable storage medium that stores circuit design information.

While embodiments described in this disclosure may be susceptible to various modifications and alternative forms, specific embodiments thereof are shown by way of example in the drawings and will herein be described in detail. It should be understood, however, that the drawings and detailed description thereto are not intended to limit the embodiments to the particular form disclosed but, on the contrary, the intention is to cover all modifications, equivalents and alternatives falling within the spirit and scope of the appended claims.

### DETAILED DESCRIPTION OF EMBODIMENTS

Some signals received by, or generated by, a computer system may require amplification before use. For example, before digital processing may be performed on a signal received via an antenna, the signal may need to be amplified so that it can be properly converted into the digital domain. In other cases, the magnitude of a signal generated by the computer system may need to be increased in order to drive a peripheral element, e.g., a speaker, connected to the computer system. Computer systems employ a variety of amplifier circuits to increase the magnitude of such signals.

There are various types of amplifier circuits that may be employed. Depending on the application, different amplifier circuits may be used. For example, when high fidelity is required for audio amplification, a Class A amplifier circuit may be employed. Class A amplifier circuits, however, conduct during the entire period of an input signal to be amplified, making them inefficient from a power standpoint. If power efficiency of the amplifier circuit is a concern, other classes of amplifier circuits may be employed. For example, a Class B amplifier circuit or Class AB amplifier circuit may be employed, trading off fidelity for efficiency.

Another common type of amplifier circuit that is used in computer systems is a switching amplifier circuit (also referred to as a “Class D amplifier circuit”). Switching amplifier circuits have a similar circuit topology to a buck DC-DC power converter circuit, and operate by generating a train of rectangular pulses of fixed amplitude with varying widths or frequencies. The variation in the width of the pulses or the number of pulses per time, i.e., the frequency of the pulses, corresponds to amplitude variations of the input signal. Since the active devices or transistors in a switching amplifier circuit are operating as switches, losses associated with operating such devices or transistors in a linear mode of operation can be reduced, resulting in high power efficiency.

Switching amplifier circuits allow for high output power with a high efficiency. Additionally, switching amplifier circuits have low noise and distortion, and do not necessarily need additional filter circuits, which makes them ideal for many applications such as audio. Another advantage of switching amplifier circuits is that since the active devices or transistors operate as switching elements instead of linear gain devices, some switching amplifier circuits may use a digital signal, i.e., a stream of one or more bits, directly eliminating the need for digital to analog conversion.

In some applications, the gain requirements can result in the output signal of a switching amplifier circuit to reach the voltage level of the power supply coupled to the switching devices. When this occurs, the output signal is “clipped” to the voltage level of the power supply coupled to the switching devices or transistors, distorting the output signal.

To reduce clipping in the output signal, power supply voltage levels for the switching devices in a switching amplifier circuit are often increased to provide additional headroom between the maximum level of the output signal and the voltage level of the power supply.

While reducing clipping, increasing the voltage level of the power supply causes the output signal(s) of a switching amplifier circuit to transition over a larger voltage range, reducing efficiency, increasing electromagnetic interference (EMI), and increasing power consumption. To reduce such power consumption, some switching amplifier circuits adjust the ground level (referred to as “ground lifting”) of the switching devices so they devices only have to switch over a voltage range needed to track the input signal.

The adjustments made to the power and ground connections of the switching devices are commonly made in a discrete fashion, as in a class G amplifier circuit. In other words, the values for the power supply and the ground supply of the switching devices can only assume certain discrete values. As the magnitude of the input signal changes, the power supply and ground supply are switched between the various discrete values. The solution, however, can result in distortion in the output signal as the power and ground supplies transition abruptly from one value to another.

The embodiments described herein employ power and ground supply circuits that allow for the adjustment of a switching amplifier circuit's power and ground values over respective continuous ranges of voltages as a function of the magnitude of an input signal. By continuously adjusting the values of the power and ground levels for a switching amplifier circuit, power dissipation can be reduced while preventing distortion associated with the restricting the power and ground voltages to discrete levels.

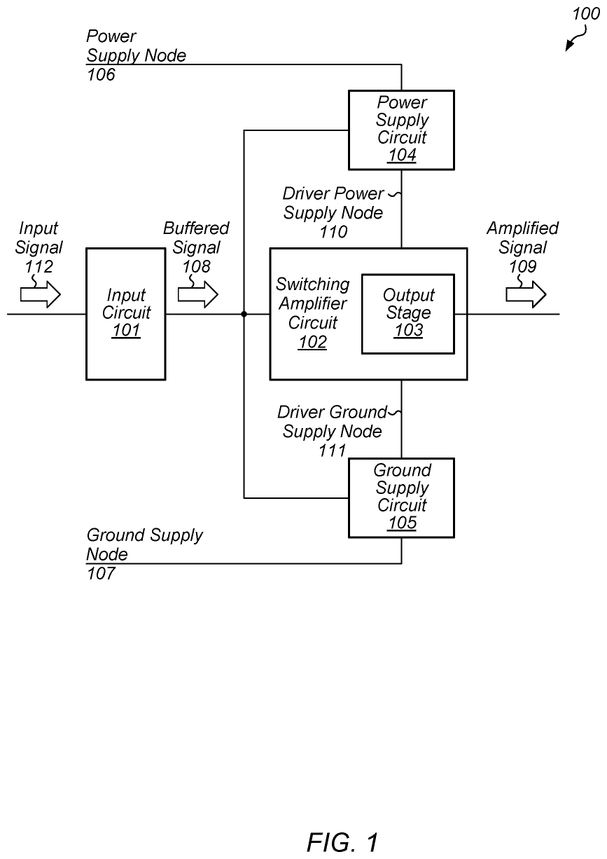

A block diagram of a supply tracking amplifier circuit is depicted in FIG. 1. As illustrated, supply tracking amplifier circuit 100 includes input circuit 101, switching amplifier circuit 102 that includes output stage 103, power supply circuit 104, and ground supply circuit 105.

Input circuit 101 is configured to receive input signal 112 and generate buffered signal 108. In some embodiments, input signal 112 and buffered signal 108 may be analog signals. In such cases, input circuit 101 may include any suitable combination of amplifier and filter circuits configured to generate buffered signal 108.

Power supply circuit 104 is configured to adjust, based on a magnitude of buffered signal 108, a voltage of driver power supply node 110 over a first continuous range of voltages. In various embodiments, the first continuous range of voltages may include voltages greater than or less than the voltage level of power supply node 106. As used herein, a continuous range of voltages refers to any voltage between a minimum voltage and a maximum voltage associated with the continuous range.

Ground supply circuit 105 is configured to adjust a voltage level of driver ground supply node 111 over a second continuous range of voltages. It is noted that the second continuous range of voltages is different from the first continuous range of voltages although, in some embodiments, there may be an overlap between the first continuous range of voltages and the second continuous range of voltages. It is noted that, in some embodiments, the second continuous range of voltages may include voltages less than the voltage of ground supply node 107, as well as voltage greater than the voltage of ground supply node 107.

Both power supply circuit 104 and ground supply circuit 105 may, in various embodiment, be implemented using charge pump circuits. In other embodiments, power supply circuit 104 and ground supply circuit 105 may be implemented using buck converter circuits, boost converter circuits, buck-boost converter circuits, pass-through switches, current-limiting switches, or any other suitable type of converter circuit.

Switching amplifier circuit 102 is configured to generate amplified signal 109, which is an amplified version of buffered signal 108, that switches between the voltage level of driver power supply node 110 and the voltage level of driver ground node 105. In various embodiments, output stage 103 is coupled to driver power supply node 110 and ground supply node 111, while other circuitry included in switching amplifier circuit 102 is coupled to power supply node 106 and ground supply node 107.

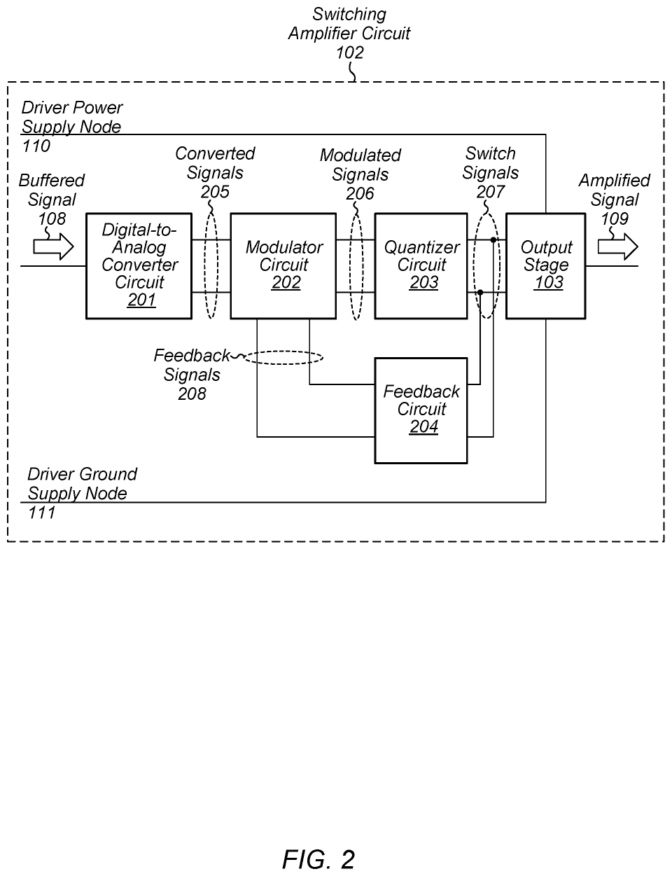

Turning to FIG. 2, a block diagram of switching amplifier circuit 102 is depicted. As illustrated, switching amplifier circuit 102 includes digital-to-analog converter circuit 201, modulator circuit 202, quantizer circuit 203, feedback circuit 204, and output stage 103. It is noted that the embodiment of switching amplifier circuit 102 depicted in FIG. 2 employs differential signaling. In other embodiments, switching amplifier circuit 102 may employ singled-ended signaling.

Digital-to-analog converter circuit 201 is configured to generate converted signals 205 using buffered signal 108. To generate converted signals 205, digital-to-analog converter circuit 201 may be configured to generate respective voltage levels for converted signals 205 such that a difference between the respective voltage levels of converted signals 205 correspond to a magnitude of bits included in buffered signals 108 at any given point in time. Digital-to-analog converter circuit 201 may be implemented using a switched-resistor circuit, a switch-current source circuit, a switched-capacitor circuit, or any other suitable circuit.

Modulator circuit 202 is configured to generate modulated signals 206 using converted signals 205 and feedback signals 208. In various embodiments, to generate modulated signals 206, modulator circuit 202 may be configured to compare converted signals 205 and feedback signals 208, and integrate a voltage corresponding to a difference between converted signals 205 and feedback signals 208. Modulator circuit 202 may be implemented using a differential amplifier circuit and discrete-time capacitor or continuous-time integrator circuits.

Quantizer circuit 203 is configured to generate switch signals 207 using modulated signals 206. In various embodiments, quantizer circuit 203 may be configured to compare modulated signals 207 to triangle wave signals. As the respective voltage levels of modulated signals 206 intersect the voltage levels of the triangle wave signals, the logical state of switch signals 207 are changed. Quantizer circuit 203 may, in various embodiments, be configured to generate switch signals 207 such that switch signals 207 include a series of pulses whose respective widths or frequencies vary according to the amplitude differentially encoded in modulated signals 206 in a process referred to as “pulse-width modulation” or “pulse-density modulation.” Quantizer circuit 203 may be implemented using a triangle wave generator circuit and any suitable comparator circuit configured to generate a digital output based on a comparison of at least two analog signals such as a Schmitt trigger circuit.

Feedback circuit 204 is configured to generate feedback signals 208 using switch signals 207. To generate feedback signals 208, feedback circuit 204 may perform a digital-to-analog conversion operation such that a difference between the respective voltage levels for feedback signals 208 correspond to a magnitude of a signal encoded by the pulse-width modulation switch signals 207. Feedback circuit 204 may be implemented using a switched-resistor circuit, a switch-current source circuit, a switched-capacitor circuit, or any other suitable digital-to-analog converter circuit.

Output stage 103 is configured to generate amplified signal 109 using switch signals 207. As described below, different ones of switch signals 207 may control corresponding switch devices in output stage 103. For example, when a given one of switch signals 207 is active, output stage 103 may couple its output node to driver power supply node 110 such that a voltage level of amplified signal 109 is at or near the voltage level of driver power supply node 110. Alternatively, when a different one of switch signals 207 is active, output stage 103 may couple its output node to driver ground supply node 111 such that a voltage level of amplifier signal 109 is at or near the voltage level of driver ground supply node 111.

As used herein, when a signal is activated, it is set to a logic or voltage level that activates a load circuit or device, and when a signal is deactivated, it is set to a logic or voltage level that deactivates the load circuit or device. The logic level may be either a high logic level or a low logic level depending on the load circuit. For example, an active state of a signal coupled to a p-channel MOSFET is a low logic level (referred to as an “active low signal”), while an active state of a signal coupled to an n-channel MOSFET is a high logic level (referred to as an “active high signal”).

It is noted that the embodiment of switching amplifier circuit 102 depicted in FIG. 2 is merely an example. In other embodiments, different switching amplifier circuit topologies may be employed. For example, in some cases when input signal 112 is an analog signal, digital-to-analog converter circuit 201 may be omitted.

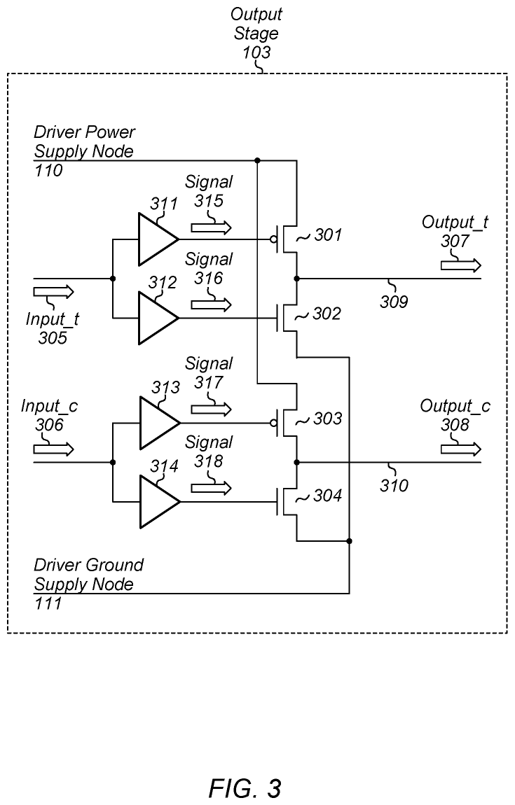

A block diagram of an embodiment of output stage 103 is depicted in FIG. 3. As illustrated, output stage 103 includes transistors 301-304 and pre-driver circuits 311-314. It is noted that, although transistors 301-304 are depicted as single transistors, in other embodiments, any of transistors 301-304 may be implemented using multiple transistors coupled together in parallel or in series.

Pre-driver circuits 311 and 312 are configured, using input_t 305, to generate signals 315 and 316, respectively. In a similar fashion, pre-driver circuits 313 and 314 are configured, using input_c 306, to generate signals 317 and 318, respectively. In various embodiments, signals 315 and 316 are buffered versions of input_t 305, while signals 317 and 318 are buffered versions of input_c 306. Pre-driver circuits 311-314 may be implemented using multiple inverter circuits or any suitable non-inverting amplifier circuits. It is noted that input_t 305 and input_c 306 may be included in switch signals 207 as depicted in FIG. 2. In some embodiments, a single input signal may be employed.

Transistor 301 is coupled between driver power supply node 110 and node 309, while transistor 302 is coupled between node 309 and driver ground supply node 111. Transistor 301 is controlled by signal 315, while transistor 302 is controlled by signal 316. In a similar fashion, transistor 303 is coupled between driver power supply node 110 and node 310, while transistor 304 is coupled between node 310 and driver ground supply node 111. Transistor 303 is controlled by signal 317 and transistor 304 is controlled by signal 318.

In response to an activation of transistor 302, node 309 is discharged into driver ground supply node 111 and the voltage level of output_t 307 decreases to the voltage level of driver ground supply node 111. In response to an activation of transistor 303, node 310 is coupled to driver power supply node 110 and the voltage level of output_c 308 increases to the voltage level of driver power supply node 110.

In response to an activation of transistor 301, node 309 is coupled to driver power supply node 110 and the voltage level of output_t 307 increases to the voltage level of driver power supply node 110. In response to an activation of transistor 304, node 310 is discharged into driver ground supply node 111 and the voltage level of output_c 308 decreases to the voltage level of driver ground supply node 111.

In various embodiments, transistors 301 and 303 may be implemented using p-channel metal-oxide semiconductor field-effect transistors (MOSFETs), fin field-effect transistors (FinFETs), gate-all-around field-effect transistors (GAAFETs), or any other suitable type of transconductance devices. Transistors 302 and 304 may, in various embodiments, be implemented using n-channel MOSFETs, FinFETs, GAAFETs, or any other suitable type of transconductance devices.

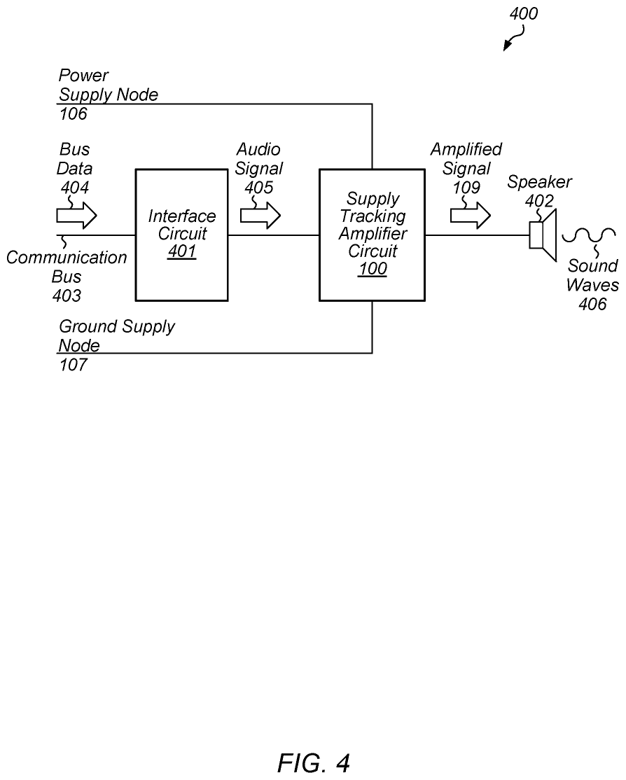

Turning to FIG. 4, a block diagram of an audio sub-system is depicted. As illustrated, audio sub-system 400 includes supply tracking amplifier circuit 100, interface circuit 401, and speaker 402.

Interface circuit 401 is coupled to communication bus 403 and is configured to receive bus data 404 and generate audio signal 405 using bus data 404. In various embodiments, bus data 404 may be encoded according to a communication protocol for communication bus 403. For example, bus data 404 may be encoded according to the Peripheral Component Interconnect Express (“PCIe”) communication protocol, or any other suitable communication protocol.

In some embodiments, audio signal 405 may be an analog signal, while in other embodiments, audio signal 405 may be a digital signal that includes a stream of words, each of which includes multiple bits whose value corresponds to a magnitude of audio signal 405. In cases where audio signal 405 is a digital signal, supply tracking amplifier circuit 100 may not include input circuit 101 and may be configured to directly use audio signal 405. In cases where audio signal 405 is an analog signal, switching amplifier circuit 102 may not include digital-to-analog converter circuit 201 and may be configured to directly use buffered signal 108.

In various embodiments, interface circuit 401 may be implemented using any suitable combination of combinatorial and sequential logic circuits. In some embodiments, interface circuit 401 may be implemented using a microcontroller or any other suitable processor circuit. In cases where audio signal 405 is an analog signal, interface circuit 401 may include a digital-to-analog converter (“DAC”) circuit.

Supply tracking amplifier circuit 100 is configured to generate amplified signal 109 using audio signal 405. As described above, supply tracking amplifier circuit 100 is configured to generate voltage levels on driver power supply node 110 and driver ground supply node 111 based on the respective voltage levels of power supply node 106 and ground supply node 107, and based on a magnitude of audio signal 405. By continuously adjusting the voltage levels of driver power supply node 110 and driver ground supply node 111, supply tracking amplifier circuit 100 may generate amplified signal 109 with minimum distortion, better electro-magnetic interference characteristics, and the like.

Speaker 402 is configured to generate sound waves 406 using amplified signal 109. It is noted that although amplified signal 109 is depicted as being a single wire, in other embodiments, amplified signal 109 may be a differential signal and speaker 402 may be coupled between the two signals that are included in the differential signal.

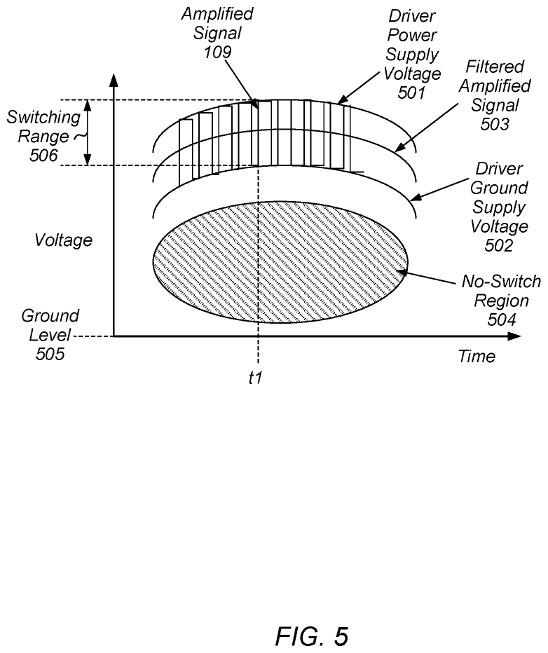

Example waveforms depicting the switching range of a switching amplifier circuit are illustrated in FIG. 5. It is noted that driver power supply voltage 501 and drive ground voltage 502 may correspond to the respective voltage levels of driver power supply node 110 and driver ground supply node 111. Additionally, filtered amplified signal 503 may correspond to a voltage level resulting from amplified signal 109 being filtered by reactive circuit elements such as inductors, capacitors, or reactive circuit elements in the load itself.

The respective magnitudes of driver power supply voltage 501 and driver ground supply voltage 502 track the magnitude of filtered amplified signal 503. As the voltage level of filtered amplified signal 503 increase, so do the respective levels of driver power supply voltage 501 and driver ground supply voltage 502.

At any given point in time, the available switching range for amplified signal 109 is between the respective levels of driver power supply voltage 501 and driver ground supply voltage 502. For example, at time t1, amplified signal 109 may transition within switching range 506. Depending on the characteristics of the load, a size of switching range 506 may be adjusted to ensure that filtered amplified signal 503 does not exceed the switching range resulting in distortion. In various embodiments, both power supply circuit 104 and ground supply circuit 105 may be configured to adjust the amount of extra headroom to be provided for filtered amplified signal 503.

As described above, ground supply circuit 105 may be configured to generate voltage levels on driver ground supply node 111 that are positive relative to ground supply node 107 (depicted as ground level 505). By generating such voltage levels on driver ground supply node 111, amplified signal 109 does not switch within no-switch region 504. Preventing amplified signal 109 from discharging all the way to ground level 505 can reduce power consumption and electromagnetic interference (EMI) in various embodiments.

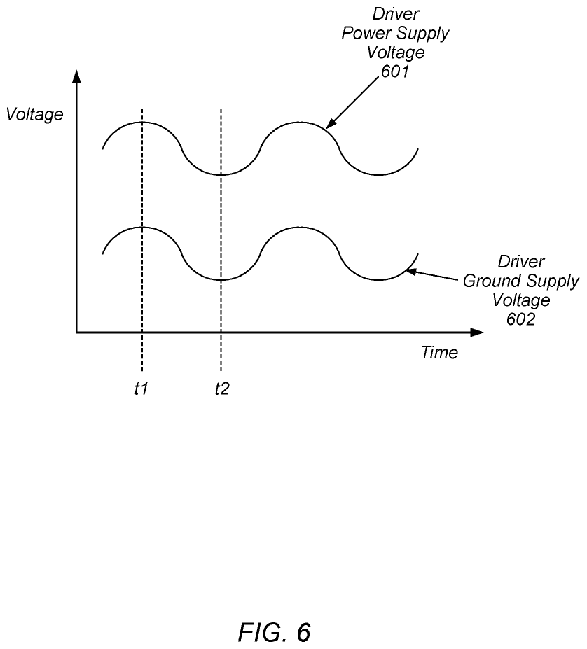

Turning to FIG. 6, example waveforms associated with the adjustment of driver power and ground levels for a switching amplifier circuit are depicted. It is noted that driver power supply voltage 601 and driver ground supply voltage 602 may correspond to respective voltage levels of driver power supply node 110 and driver ground supply node 111.

In the illustrated example, driver power supply voltage 601 and driver ground supply voltage 602 are adjusted in phase with each other. In such cases, power supply circuit 104 and ground supply circuit 105 are configured to jointly adjust the respective voltage levels of driver power supply node 110 and driver ground supply node 111.

At time t1, both driver power supply voltage 601 and driver ground supply voltage 602 are set to local maximum voltage levels based on a magnitude of buffered signal 108. At time t2, both driver power supply voltage 601 and driver ground supply voltage 602 are set to local minimum values based on the magnitude of buffered signal 108. The adjustment of driver power supply voltage 601 and driver ground supply voltage 602 can then continue after time t2 as the magnitude of buffered signal 108 changes. Although the time interval between maximum and minimum values of driver power supply voltage 601 and driver ground supply voltage 602 are depicted as being periodic, in other embodiments, periods of local maxima and minima may occur at any time based on variations in buffered signal 108.

It is noted that, in the illustrated embodiment, the respective amount of adjustment performed to driver power supply voltage 601 and driver ground supply voltage 602 is the same. As described below, in other cases, driver power supply voltage 601 and driver ground supply voltage 602 may be adjusted by different amounts.

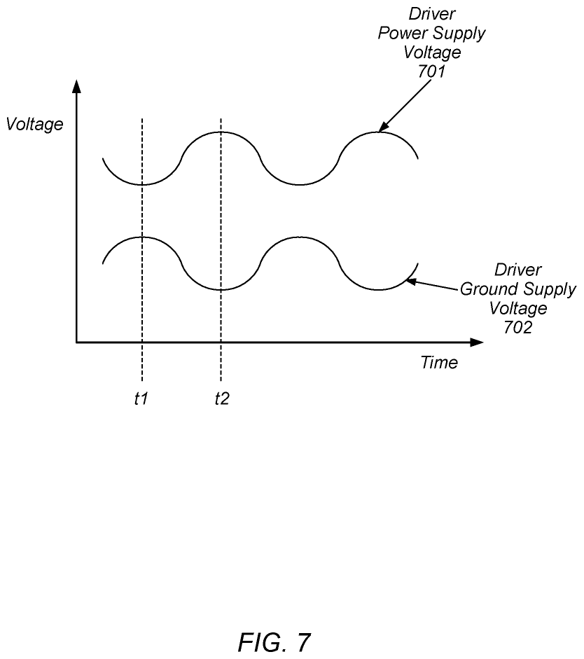

Turning to FIG. 7, different example waveforms associated with the adjustment of driver power and ground levels for a switching amplifier circuit are depicted. It is noted that driver power supply voltage 701 and driver ground supply voltage 702 may correspond to respective voltage levels of driver power supply node 110 and ground supply node 111.

In the illustrated example, driver power supply voltage 701 and driver ground supply voltage 702 are adjusted out-of-phase with each other. In such cases, power supply circuit 104 and ground supply circuit 105 are configured to adjust the respective voltage levels of driver power supply node 110 and driver ground supply node 111 out-of-phase with each. Unlike in-phase operation, out-of-phase operation allows for one of driver power supply voltage 701 and driver ground supply voltage 702 to be set to a local maximum value, while the other is to a local minimum value.

At time t1, driver power supply voltage 701 is set to a local minimum voltage, while driver ground supply voltage 702 are set to a local maximum voltage level based on a magnitude of buffered signal 108. At time t2, driver power supply voltage 701 is set to a local maximum voltage level, while driver ground supply voltage 702 are set to a local minimum voltage level based on the magnitude of buffered signal 108. The adjustment of driver power supply voltage 701 and driver ground supply voltage 702 can then continue after time t2 as the magnitude of buffered signal 108 changes. Although the time interval between maximum and minimum values of driver power supply voltage 701 and driver ground supply voltage 702 are depicted as being periodic, in other embodiments, periods of local maxima and minima may occur at any time based on variations in buffered signal 108.

It is noted that, in the illustrated embodiment, the respective amount of adjustment performed to driver power supply voltage 701 and driver ground supply voltage 702 is the same. As described below, in other cases, driver power supply voltage 701 and driver ground supply voltage 702 may be adjusted by different amounts.

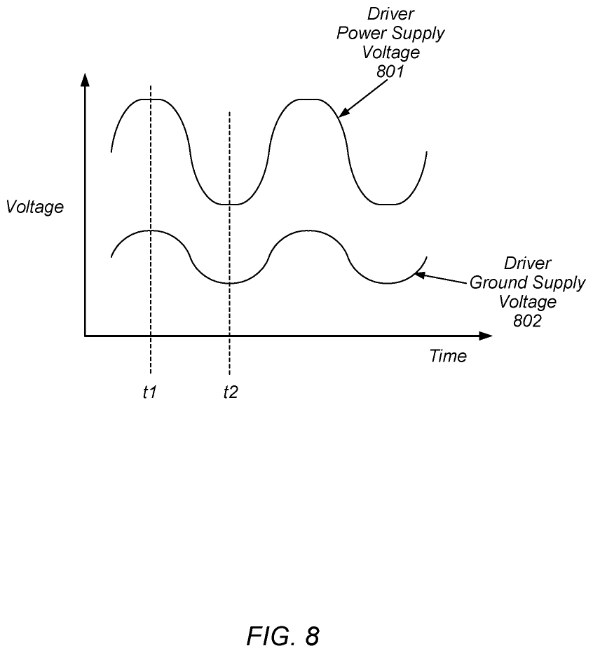

Turning to FIG. 8, alternative example waveforms associated with the adjustment of driver power and ground levels for a switching amplifier circuit are depicted. It is noted that driver power supply voltage 801 and driver ground supply voltage 802 may correspond to respective voltage levels of driver power supply node 110 and driver ground supply node 111.

In the illustrated example, driver power supply voltage 801 and driver ground supply voltage 802 are adjusted in phase with each other, but the respective magnitudes of the adjustments are different. In such cases, power supply circuit 104 and ground supply circuit 105 are configured to adjust the respective voltage levels of driver power supply node 110 and driver ground supply node 111 by different amounts. By using a combination of the techniques depicted in FIGS. 6-8, the respective voltage levels of driver power supply node 110 and driver ground supply node 111 can be adjusted to accommodate a wide variety of input signals.

At time t1, both driver power supply voltage 801 and driver ground supply voltage 802 are set to corresponding local maximum voltages. At time t2, both driver power supply voltage 801 and driver ground supply voltage 802 are set to corresponding local minimum voltages. It is noted that the difference between the local maximum voltage and the local minimum voltage for driver power supply voltage 801 is greater than the difference between the local maximum voltage and the local minimum voltage for driver ground supply voltage 802. In other embodiments, the difference between the local maximum voltage and the local minimum voltage for driver power supply voltage 801 may be less than the difference between the local maximum voltage and the local minimum voltage for driver ground supply voltage 802.

Although it is depicted in FIG. 8 that the respective voltage ranges for driver power supply voltage 801 and driver ground supply voltage 802 remain constant over time, in other embodiments, the respective voltage ranges may vary independently over time as a function of the characteristics of input signal 112. It is further noted that employing different voltage ranges for driver power supply voltage 801 and driver ground supply voltage 802 may be used in combination with either in-phase or out-of-phase operation as described above.

To summarize, various embodiments of a supply tracking amplifier circuit are disclosed. Broadly speaking, a supply tracking amplifier circuit includes an input circuit, a power supply circuit, a ground supply circuit, and a switching amplifier circuit. The input circuit may be configured to receive an input signal and generate a buffered signal using the input signal. The power supply circuit may be configured to adjust, based on a magnitude of the buffered signal, a voltage of a driver power supply node over a first continuous range of voltages, while the ground supply circuit may be configured to adjust, based on the magnitude of the buffered signal, a voltage of a driver ground supply node over a second continuous range of voltages. The switching amplifier circuit may be configured to generate an amplified version of the buffered signal that switches between the voltage level of the driver power supply node and the voltage level of the driver ground supply node.

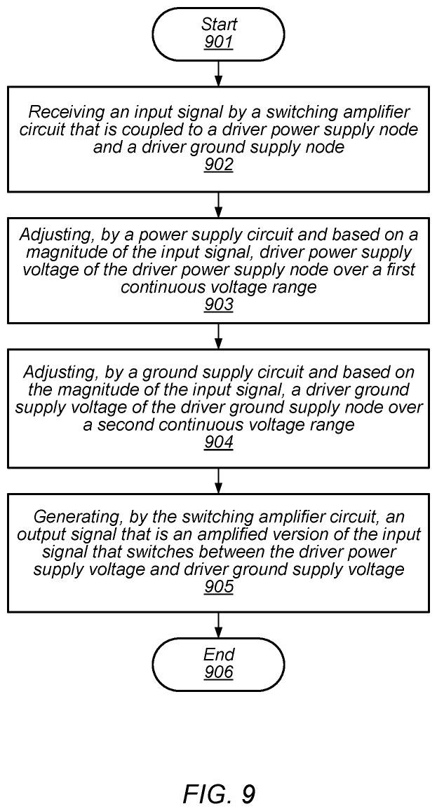

Turning to FIG. 9, a flow diagram depicting an embodiment of a method for operating a supply-tracking switching amplifier circuit is illustrated. The method, which begins in block 901, may be applied to various supply tracking amplifier circuits, such as supply tracking amplifier circuit 100 as illustrated in FIG. 1.

The method includes receiving an input signal by a supply tracking amplifier circuit that includes a switching amplifier circuit, a power supply circuit, and a ground supply circuit, wherein the switching amplifier circuit is coupled to a driver power supply node and a driver ground supply node (block 902). In some embodiments, the input signal can include a plurality of data packets encoded according to a communication protocol. In such cases, the method can further include translating, by a buffer circuit included in the supply tracking amplifier circuit, the plurality of data packets to a plurality of words that include respective pluralities of bits.

The method further includes adjusting, by the power supply circuit and based on a magnitude of the input signal, a driver power supply voltage of the driver power supply node over a first continuous voltage range (block 903). In various embodiments, adjusting the driver power supply voltage includes increasing the driver power supply voltage in response to determining that the magnitude of the input signal has increased.

The method also includes adjusting, by the ground supply circuit and based on the magnitude of the input signal, a driver ground supply voltage of the driver ground supply node over a second continuous voltage range (block 904). In some embodiments, adjusting the driver ground supply voltage includes increasing the driver ground supply voltage relative to a ground reference. In other embodiments, adjusting the driver ground supply voltage includes decreasing the driver ground supply voltage relative to the ground reference.

In some embodiments, the method may include adjusting the driver ground supply voltage in phase with adjusting the driver power supply voltage. In other embodiments, the method can also include adjusting the driver ground supply voltage out-of-phase with adjusting the driver power supply voltage.

The method further includes generating, by the switching amplifier circuit, an output signal that is an amplified version of the input signal that switches between the driver power supply voltage and the driver ground supply voltage (block 905). The method concludes in block 906.

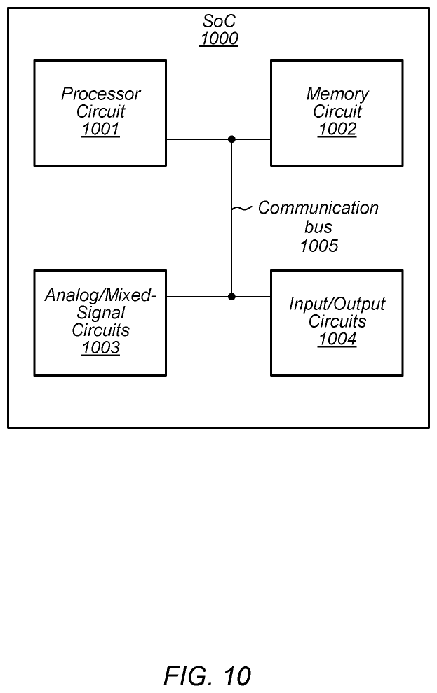

A block diagram of a system-on-a-chip (SoC) is illustrated in FIG. 10. In the illustrated embodiment, SoC 1000 includes processor circuit 1001, memory circuit 1002, analog/mixed-signal circuits 1003, and input/output circuits 1004, each of which is coupled to communication bus 1005. In various embodiments, SoC 1000 may be configured for use in a desktop computer, server, or in a mobile computing application such as, e.g., a tablet, laptop computer, or wearable computing device.

Processor circuit 1001 may, in various embodiments, be representative of a general-purpose processor that performs computational operations. For example, processor circuit 1001 may be a central processing unit (CPU) such as a microprocessor, a microcontroller, an application-specific integrated circuit (ASIC), or a field-programmable gate array (FPGA).

Memory circuit 1002 may, in various embodiments, include any suitable type of memory such as a Dynamic Random-Access Memory (DRAM), a Static Random-Access Memory (SRAM), a Read-Only Memory (ROM), an Electrically Erasable Programmable Read-only Memory (EEPROM), or a non-volatile memory, for example. It is noted that although a single memory circuit is illustrated in FIG. 10, in other embodiments, any suitable number of memory circuits may be employed.

Analog/mixed-signal circuits 1003 may include a crystal oscillator circuit, a phase-locked loop (PLL) circuit, an analog-to-digital converter (ADC) circuit, and a digital-to-analog converter (DAC) circuit (all not shown). In other embodiments, analog/mixed-signal circuits 1003 may be configured to perform power management tasks with the inclusion of on-chip power supplies and voltage regulator circuits

Input/output circuits 1004 may include supply tracking amplifier circuit 100, and may be configured to coordinate data transfer between SoC 1000 and one or more peripheral devices. Such peripheral devices may include, without limitation, storage devices (e.g., magnetic or optical media-based storage devices including hard drives, tape drives, CD drives, DVD drives, etc.), audio processing subsystems, or any other suitable type of peripheral devices. In some embodiments, input/output circuits 1004 may be configured to implement a version of Universal Serial Bus (USB) protocol or IEEE 1394 (Firewire®) protocol.

Input/output circuits 1004 may also be configured to coordinate data transfer between SoC 1000 and one or more devices (e.g., other computing systems or integrated circuits) coupled to SoC 1000 via a network. In one embodiment, input/output circuits 1004 may be configured to perform the data processing necessary to implement an Ethernet (IEEE 802.3) networking standard such as Gigabit Ethernet or 10-Gigabit Ethernet, for example, although it is contemplated that any suitable networking standard may be implemented. In some embodiments, input/output circuits 1004 may be configured to implement multiple discrete network interface ports.

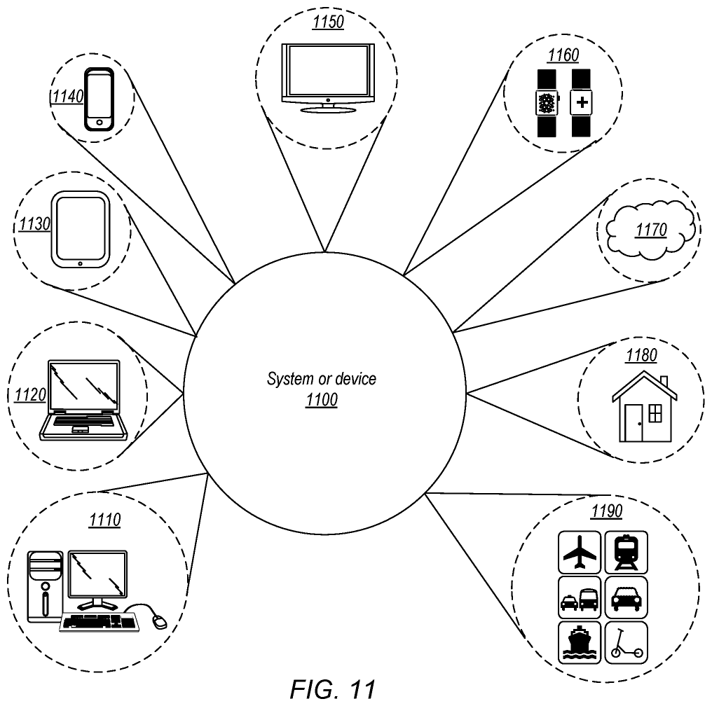

Turning now to FIG. 11, various types of systems that may include any of the circuits, devices, or systems discussed above are illustrated. System or device 1100, which may incorporate or otherwise utilize one or more of the techniques described herein, may be utilized in a wide range of areas. For example, system or device 1100 may be utilized as part of the hardware of systems such as a desktop computer 1110, laptop computer 1120, tablet computer 1130, cellular or mobile phone 1140, or television 1150 (or set-top box coupled to a television).

Similarly, disclosed elements may be utilized in a wearable device 1160, such as a smartwatch or a health-monitoring device. Smartwatches, in many embodiments, may implement a variety of different functions—for example, access to email, cellular service, calendar, health monitoring, etc. A wearable device may also be designed solely to perform health-monitoring functions, such as monitoring a user's vital signs, performing epidemiological functions such as contact tracing, providing communication to an emergency medical service, etc. Other types of devices are also contemplated, including devices worn on the neck, devices implantable in the human body, glasses or a helmet designed to provide computer-generated reality experiences such as those based on augmented and/or virtual reality, etc.

System or device 1100 may also be used in various other contexts. For example, system or device 1100 may be utilized in the context of a server computer system, such as a dedicated server or on shared hardware that implements a cloud-based service 1170. Still further, system or device 1100 may be implemented in a wide range of specialized everyday devices, including devices 1180 commonly found in the home such as refrigerators, thermostats, security cameras, etc. The interconnection of such devices is often referred to as the “Internet of Things” (IoT). Elements may also be implemented in various modes of transportation. For example, system or device 1100 could be employed in the control systems, guidance systems, entertainment systems, etc. of various types of vehicles 1190.

The applications illustrated in FIG. 11 are merely exemplary and are not intended to limit the potential future applications of disclosed systems or devices. Other example applications include, without limitation: portable gaming devices, music players, data storage devices, unmanned aerial vehicles, etc.

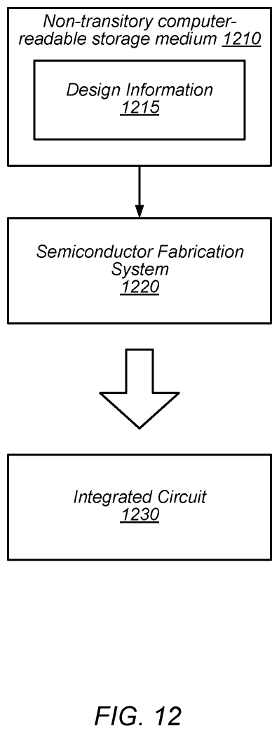

FIG. 12 is a block diagram illustrating an example of a non-transitory computer-readable storage medium that stores circuit design information, according to some embodiments. In the illustrated embodiment, semiconductor fabrication system 1220 is configured to process design information 1215 stored on non-transitory computer-readable storage medium 1210 and fabricate integrated circuit 1230 based on design information 1215.

Non-transitory computer-readable storage medium 1210 may comprise any of various appropriate types of memory devices or storage devices. Non-transitory computer-readable storage medium 1210 may be an installation medium, e.g., a CD-ROM, floppy disks, or tape device; a computer system memory or random-access memory such as DRAM, DDR RAM, SRAM, EDO RAM, Rambus RAM, etc.; a non-volatile memory such as Flash, magnetic media, e.g., a hard drive, or optical storage; registers, or other similar types of memory elements, etc. Non-transitory computer-readable storage medium 1210 may include other types of non-transitory memory as well or combinations thereof. Non-transitory computer-readable storage medium 1210 may include two or more memory mediums, which may reside in different locations, e.g., in different computer systems that are connected over a network.

Design information 1215 may be specified using any of various appropriate computer languages, including hardware description languages such as, without limitation: VHDL, Verilog, SystemC, SystemVerilog, RHDL, M, MyHDL, etc. Design information 1215 may be usable by semiconductor fabrication system 1220 to fabricate at least a portion of integrated circuit 1230. The format of design information 1215 may be recognized by at least one semiconductor fabrication system, such as semiconductor fabrication system 1220, for example. In some embodiments, design information 1215 may include a netlist that specifies elements of a cell library, as well as their connectivity. One or more cell libraries used during logic synthesis of circuits included in integrated circuit 1230 may also be included in design information 1215. Such cell libraries may include information indicative of device or transistor-level netlists, mask design data, characterization data, and the like, of cells included in the cell library.

Integrated circuit 1230 may, in various embodiments, include one or more custom macrocells, such as memories, analog or mixed-signal circuits, and the like. In such cases, design information 1215 may include information related to included macrocells. Such information may include, without limitation, schematics capture database, mask design data, behavioral models, and device or transistor-level netlists. As used herein, mask design data may be formatted according to graphic data system (GDSII), or any other suitable format.

Semiconductor fabrication system 1220 may include any of various appropriate elements configured to fabricate integrated circuits. This may include, for example, elements for depositing semiconductor materials (e.g., on a wafer, which may include masking), removing materials, altering the shape of deposited materials, modifying materials (e.g., by doping materials or modifying dielectric constants using ultraviolet processing), etc. Semiconductor fabrication system 1220 may also be configured to perform various testing of fabricated circuits for correct operation.

In various embodiments, integrated circuit 1230 is configured to operate according to a circuit design specified by design information 1215, which may include performing any of the functionality described herein. For example, integrated circuit 1230 may include any of various elements shown or described herein. Further, integrated circuit 1230 may be configured to perform various functions described herein in conjunction with other components. Further, the functionality described herein may be performed by multiple connected integrated circuits.

As used herein, a phrase of the form “design information that specifies a design of a circuit configured to . . . ” does not imply that the circuit in question must be fabricated in order for the element to be met. Rather, this phrase indicates that the design information describes a circuit that, upon being fabricated, will be configured to perform the indicated actions or will include the specified components.

The present disclosure includes references to “embodiments,” which are non-limiting implementations of the disclosed concepts. References to “an embodiment,” “one embodiment,” “a particular embodiment,” “some embodiments,” “various embodiments,” and the like do not necessarily refer to the same embodiment. A large number of possible embodiments are contemplated, including specific embodiments described in detail, as well as modifications or alternatives that fall within the spirit or scope of the disclosure. Not all embodiments will necessarily manifest any or all of the potential advantages described herein.

Unless stated otherwise, the specific embodiments are not intended to limit the scope of claims that are drafted based on this disclosure to the disclosed forms, even where only a single example is described with respect to a particular feature. The disclosed embodiments are thus intended to be illustrative rather than restrictive, absent any statements to the contrary. The application is intended to cover such alternatives, modifications, and equivalents that would be apparent to a person skilled in the art having the benefit of this disclosure.

Particular features, structures, or characteristics may be combined in any suitable manner consistent with this disclosure. The disclosure is thus intended to include any feature or combination of features disclosed herein (either explicitly or implicitly), or any generalization thereof. Accordingly, new claims may be formulated during prosecution of this application (or an application claiming priority thereto) to any such combination of features. In particular, with reference to the appended claims, features from dependent claims may be combined with those of the independent claims and features from respective independent claims may be combined in any appropriate manner and not merely in the specific combinations enumerated in the appended claims.

For example, while the appended dependent claims are drafted such that each depends on a single other claim, additional dependencies are also contemplated. Where appropriate, it is also contemplated that claims drafted in one statutory type (e.g., apparatus) suggest corresponding claims of another statutory type (e.g., method).

Because this disclosure is a legal document, various terms and phrases may be subject to administrative and judicial interpretation. Public notice is hereby given that the following paragraphs, as well as definitions provided throughout the disclosure, are to be used in determining how to interpret claims that are drafted based on this disclosure.

References to the singular forms such “a,” “an,” and “the” are intended to mean “one or more” unless the context dictates otherwise. Reference to “an item” in a claim thus does not preclude additional instances of the item.

The word “may” is used herein in a permissive sense (i.e., having the potential to, being able to) and not in a mandatory sense (i.e., must).

The terms “comprising” and “including,” and forms thereof, are open-ended and mean “including, but not limited to.”

When the term “or” is used in this disclosure with respect to a list of options, it will generally be understood to be used in the inclusive sense unless the context provides otherwise. Thus, a recitation of “x or y” is equivalent to “x or y, or both,” covering x but not y, y but not x, and both x and y. On the other hand, a phrase such as “either x or y, but not both” makes clear that “or” is being used in the exclusive sense.

A recitation of “w, x, y, or z, or any combination thereof” or “at least one of . . . w, x, y, and z” is intended to cover all possibilities involving a single element up to the total number of elements in the set. For example, given the set [w, x, y, z], these phrasings cover any single element of the set (e.g., w but not x, y, or z), any two elements (e.g., w and x, but not y or z), any three elements (e.g., w, x, and y, but not z), and all four elements. The phrase “at least one of . . . w, x, y, and z” thus refers to at least one element of the set [w, x, y, z], thereby covering all possible combinations in this list of options. This phrase is not to be interpreted to require that there is at least one instance of w, at least one instance of x, at least one instance of y, and at least one instance of z.

Various “labels” may proceed nouns in this disclosure. Unless context provides otherwise, different labels used for a feature (e.g., “first circuit,” “second circuit,” “particular circuit,” “given circuit,” etc.) refer to different instances of the feature. The labels “first,” “second,” and “third,” when applied to a particular feature, do not imply any type of ordering (e.g., spatial, temporal, logical, etc.), unless stated otherwise.

Within this disclosure, different entities (which may variously be referred to as “units,” “circuits,” other components, etc.) may be described or claimed as “configured” to perform one or more tasks or operations. This formulation-[entity] configured to [perform one or more tasks]—is used herein to refer to structure (i.e., something physical). More specifically, this formulation is used to indicate that this structure is arranged to perform the one or more tasks during operation. A structure can be said to be “configured to” perform some task even if the structure is not currently being operated. Thus, an entity described or recited as “configured to” perform some task refers to something physical, such as a device, circuit, memory storing program instructions executable to implement the task, etc. This phrase is not used herein to refer to something intangible.

The term “configured to” is not intended to mean “configurable to.” An unprogrammed FPGA, for example, would not be considered to be “configured to” perform some specific function. This unprogrammed FPGA may be “configurable to” perform that function, however.

Reciting in the appended claims that a structure is “configured to” perform one or more tasks is expressly intended not to invoke 35 U.S.C. § 112(f) for that claim element. Should Applicant wish to invoke Section 112(f) during prosecution, it will recite claim elements using the “means for” [performing a function] construct.

The phrase “based on” is used to describe one or more factors that affect a determination. This term does not foreclose the possibility that additional factors may affect the determination. That is, a determination may be solely based on specified factors or based on the specified factors as well as other, unspecified factors. Consider the phrase “determine A based on B.” This phrase specifies that B is a factor that is used to determine A or that affects the determination of A. This phrase does not foreclose that the determination of A may also be based on some other factor, such as C. This phrase is also intended to cover an embodiment in which A is determined based solely on B. As used herein, the phrase “based on” is synonymous with the phrase “based at least in part on.”

The phrase “in response to” describes one or more factors that trigger an effect. This phrase does not foreclose the possibility that additional factors may affect or otherwise trigger the effect. That is, an effect may be solely in response to those factors, or may be in response to the specified factors as well as other, unspecified factors. Consider the phrase “perform A in response to B.” This phrase specifies that B is a factor that triggers the performance of A. This phrase does not foreclose that performing A may also be in response to some other factor, such as C. This phrase is also intended to cover an embodiment in which A is performed solely in response to B.

What is claimed is:

1. An apparatus, comprising:
an input circuit configured to:
receive an input signal; and
generate a buffered signal using the input signal;
a power supply circuit configured to adjust, based on a magnitude of the buffered signal, a voltage level of a driver power supply node over a first continuous range of voltages;
a ground supply circuit configured to adjust, based on the magnitude of the buffered signal, a voltage level of a driver ground supply node over a second continuous range of voltages; and
a switching amplifier circuit configured to generate an amplified version of the buffered signal that switches between the voltage level of the driver power supply node and the voltage level of the driver ground supply node.

2. The apparatus of claim 1, wherein to adjust the voltage level of the driver power supply node over the first continuous range of voltages, the power supply circuit is further configured to increase the voltage level of the driver power supply node in response to a determination that the magnitude of the buffered signal has increased.

3. The apparatus of claim 1, wherein to adjust the voltage level of the driver ground supply node over the second continuous range of voltages, the ground supply circuit is further configured to decrease the voltage level of the driver ground supply node relative to a ground reference.

4. The apparatus of claim 1, wherein to adjust the voltage level of the driver ground supply node over the second continuous range of voltages, the ground supply circuit is further configured to increase the voltage level of the driver ground supply node relative to a ground reference.

5. The apparatus of claim 1, wherein to adjust the voltage level of the driver power supply node over the first continuous range of voltages, the power supply circuit is further configured to decrease the voltage level of the driver power supply node in response to a determination that the magnitude of the buffered signal has decreased.

6. The apparatus of claim 1, wherein to generate the amplified version of the buffered signal, the switching amplifier circuit is configured to:
generate a series of pulses that switch between the voltage level of the driver power supply node and the voltage level of the driver ground supply node; and
adjust respective widths of the series of pulses based on the magnitude of the buffered signal.

7. A method, comprising,
receiving an input signal by a switching amplifier circuit that is coupled to a driver power supply node and a driver ground supply node;
adjusting, by a power supply circuit and based on a magnitude of the input signal, a driver power supply voltage of the driver power supply node over a first continuous voltage range;
adjusting, by a ground supply circuit and based on the magnitude of the input signal, a driver ground supply voltage of the driver ground supply node over a second continuous voltage range; and
generating, by the switching amplifier circuit, an output signal that is an amplified version of the input signal that switches between the driver power supply voltage and the driver ground supply voltage.

8. The method of claim 7, wherein adjusting the driver power supply voltage includes increasing the driver power supply voltage in response to determining that the magnitude of the input signal has increased.

9. The method of claim 7, wherein adjusting the driver ground supply voltage includes decreasing the driver ground supply voltage relative to a ground reference.

10. The method of claim 7, wherein adjusting the driver ground supply voltage includes increasing the driver ground supply voltage relative to a ground reference.

11. The method of claim 7, further comprising adjusting the driver ground supply voltage in phase with adjusting the driver power supply voltage.

12. The method of claim 7, further comprising adjusting the driver ground supply voltage out-of-phase with the adjusting the driver power supply voltage.

13. The method of claim 7, wherein the input signal includes a plurality of data packets encoded according to a communication protocol, and further comprising:
translating, by a buffer circuit, the plurality of data packets to a plurality of words;
adjusting, by the power supply circuit using the plurality of words, the driver power supply voltage; and
adjusting, by the ground supply circuit using the plurality of words, the driver ground supply voltage.

14. An apparatus, comprising:
a supply tracking amplifier circuit including a switching amplifier circuit, wherein the supply tracking amplifier circuit is configured to:
receive an input signal;
adjust a first magnitude of a first voltage level of a driver power supply node based on a magnitude of the input signal;
adjust a second magnitude of a second voltage level of a driver ground supply node based on the magnitude of the input signal; and
generate an amplified signal based on the input signal, wherein the amplified signal switches between the first voltage level and the second voltage level; and
a speaker configured to generate sounds waves using the amplified signal.

15. The apparatus of claim 14, wherein to adjust the second magnitude of the second voltage level of the driver ground supply node, the supply tracking amplifier circuit is further configured to increase the second voltage level of the driver ground supply node in response to a determination that the magnitude of the input signal has increased.

16. The apparatus of claim 14, wherein to adjust the second magnitude of the second voltage of the driver ground supply node, the supply tracking amplifier circuit is further configured to decrease the second voltage level of the driver ground supply node relative to a ground reference.

17. The apparatus of claim 14, wherein to adjust the second magnitude of the second voltage of the driver ground supply node, the supply tracking amplifier circuit is further configured to increase the second voltage level of the driver ground supply node relative to a ground reference.

18. The apparatus of claim 14, wherein the supply tracking amplifier circuit is further configured to adjust the second magnitude of the second voltage level of the driver ground supply node in phase with adjusting the first magnitude of the first voltage level of the driver power supply node.

19. The apparatus of claim 14, wherein to generate the amplified signal, the supply tracking amplifier circuit is configured to:
generate a series of pulses that switch between the first voltage level of the driver power supply node and the second voltage level of the driver ground supply node; and
adjust a frequency of the series of pulses based on the magnitude of the input signal.

20. The apparatus of claim 14, wherein the input signal includes a plurality of data packets encoded according to a communication protocol, and wherein the supply tracking amplifier circuit is further configured to:
translate the plurality of data packets to a plurality of words;
adjust the first magnitude of the first voltage level of the driver power supply node using the plurality of words; and
adjust the second magnitude of the second voltage level of the driver ground supply node using the plurality of words.
